(19) United States
(12) Patent Application Publication
(10) Pub. No.: US 2012/0056991 A1
(43) Pub. Date: Mar. 8, 2012

(54) IMAGE SENSOR, VIDEO CAMERA, AND MICROSCOPE

(75) Inventor: René ZÜND, Widnau (CH)

(73) Assignee: LEICA MICROSYSTEMS (SCHWEIZ) AG, HEERBRUGG (CH)

(21) Appl. No.: 13/224,494

(22) Filed: Sep. 2, 2011

(30) Foreign Application Priority Data
Sep. 4, 2010 (DE) 10 2010 044 404.9

(51) Int. Cl. H04N 13/02; H01L 27/146

(52) U.S. Cl. 348/46; 250/208.1; 348/E13.074

(57) ABSTRACT

An image sensor (1a to 1d) is described, encompassing a substrate (2) as well as multiple photoelectronic image converter cells (3a to 3d) arranged thereon or therein. According to the present invention the area of the image sensor (1a to 1d) is modifiable, the modification in area occurring a) by application of a tensile or compressive force onto the elastically and/or plastically deformable substrate, or b) by application of an electrical voltage to an EAP or to a piezoelectric substrate. A video camera and a microscope encompassing such an image sensor (1a to 1d) are also described.

### CROSS REFERENCE TO RELATED APPLICATIONS

This application claims priority of German patent application number 10 2010 044 404.9 filed Sep. 4, 2010, the entire disclosure of which is incorporated by reference herein.

### FIELD OF THE INVENTION

The invention relates to an image sensor for a video camera, in particular for a video camera at a video output of a microscope, encompassing a substrate as well as multiple photoelectronic image converter cells positioned relative to one another thereon or therein. The invention further relates to a video camera for a video output of a microscope and to a microscope having an optical imaging optic, having such a video output and, attached thereto, such a video camera having such an image sensor.

### DEFINITIONS OF TERMS AND BACKGROUND OF THE INVENTION

The definitions of certain important terms and functions are explained below.

Image sensors that encompass photoelectronic image converter cells for converting an incident electromagnetic radiation (here, in particular, light radiation) into an electronic signal are used nowadays in large numbers, for example in digital cameras, conventional video cameras, in the digital video cameras of most mobile telephones, but also in the industrial and mechanical sector, e.g. robotics, quality control, earth observation, and video microscopy as well as surgical video microscopy. They are often also referred to as “videochips.”

A surgical microscope is a stereomicroscope having a binocular beam path from the main objective through to the eyepieces. It allows the observer to view the object field in three dimensions, and thus to recognize three-dimensional structures. In conjunction with surgical video microscopy, this term also encompasses the three-dimensional presentation of, or ability to present, images acquired in three dimensions (a left and a right video imaging beam path) in the video imaging beam path on a stereo display that presents in three dimensions.

A surgical microscope usually has relatively low magnification, and possesses a surgical microscope illumination system for bright and maximally natural illumination (white light) of the object field.

An object field refers for purposes of the invention not only to the viewable and, as a rule, illuminated field under a microscope, but also to every image field of any imaging optic that is imaged in the image plane of that imaging optic. For purposes of the invention, the object field is thus the original of the entire image, capturable in the image plane of the imaging optic on the image sensor, from the imaging optic.

An imaging optic is understood hereinafter as any optical system that is suitable for imaging an object field in an image plane. This includes simple lenses as well as multi-element spherical and/or aspherical optical imaging systems. In the case of video-assisted systems, the image sensor is located in the image plane of the imaging optic so that the sensor can acquire the object field imaged in the image plane. The spatial (areal) extension of the image of the object field in the image plane is determined as a function of the spatial configuration of the optical imaging optic and its imaging beam path, and by the magnification (or reduction) selected for the imaging optic.

Imaging optics often encompass a zoom optic, which is capable of imaging smaller image segments from the object field at greater size. They are generally used as stepless magnification changers and are conventionally made up principally of carefully corrected lens systems that are arranged displaceably relative to one another.

Electroactive lenses are, for purposes of the invention, lenses whose refractive power is modifiable mechanically, electromechanically, or electrophysically. Such lenses are often also referred to as “rubber lenses” and can perform functions similar to those of a conventional zoom. They are made up of an elastically deformable substrate that is transparent and has a refractive power similar to glass.

Application of a voltage to the lens causes its shape, and thereby its refractive power, to change.

Electroactive lenses of this kind are often used as a replacement for or in addition to imaging optics, so that the latter's imaging range or refractive power can be varied. As compared with conventional zooms having corrected lens systems, however, the image quality is lower when such lenses are used. On the other hand, they have the advantage of making possible, with very little space requirement, an imaging optic with large changes in magnification and variations in refractive power. They are therefore a good choice as a replacement for a conventional zoom optic. Compromises in terms of performance must of course be accepted. A conventional electroactive lens is provided, for example, by the Optotune company and offers, for example, a refractive power variation from 15 mm focal length to infinity. As a result of electro-active deformation of both sides of an Optotune lens, these lenses can replace a compact zoom optic with a single lens element.

The exemplifying construction of such known electroactive lenses is indicated in the following documents. They are often also referred to as “variable focus optics”:
WO 2010/015095 A1;
EP 2034338 A1;
WO 2006/103281 A1;
U.S. Pat. No. 6,369,954 B1; and
WO 99/18456 A1

The disclosure in WO-A1-2010/15095 derives from the aforementioned Optotune company and describes the principle used therein, according to which the optical element is an elastic solid body, for example a gel or a polymer (electroactive polymer=EAP). It encompasses a plurality of correlated electrodes that are arranged annularly one above another. An electroactive elastic material is located between these electrodes. The electroactive elastic material is framed by an annular solid wall that, among other things, provides the electrical contacts for the electrodes. When no voltage is applied, the optical element is in its relaxed state. It is, for example, flat, corresponding to a plane-parallel plate as shown by WO-A1-2010/015095 (FIG. 1). Application of a voltage causes the electrodes to move toward one another and compress the electroactive material located therebetween, so that it squeezes into the middle of the structure and changes centrally into a lens shape in the manner evident from FIG. 3 of WO-A1-2010/015095. FIGS. 9 and 10 of WO-A1-2010/015095 show further configurations and applications of these known rubber lenses. The aforementioned Figures and associated figure description from WO-A1-2010/015095 is hereby incorporated herein by reference. This refers in particular to the physics and mechanics of material deformation by means of the voltage applied to the electrodes.

A video microscope, on the other hand, is a microscope that in principle can dispense with a visual beam path because the object field is visually depicted to a user on a display. Video microscopes are often integrated into conventional surgical microscopes but also into other conventional microscopes, in the form of video beam paths or video outputs, in order to obtain additional information or to show what is happening in the surgical field to several observers simultaneously, or also simply in order to record surgical procedures or events in the surgical field. Many of these known surgical video microscopes also serve the purpose of feedback for automatic control of the surgical microscope or to inform the user better, for example by providing him or her with overlaid image information from the video microscope that is unavailable to him or her by visual observation.

A video microscope requires at least one image sensor.

An image sensor is as a rule preceded by an imaging optic, which can range from a simple lens element to multi-element spherical and/or aspherical optical imaging optics; in each case, the imaging optic images the object field in an image plane in which the image sensor is located. The spatial (areal) extension of the image of the object field in the image plane is determined as a function of the spatial configuration of the optical imaging optic and its imaging beam path, and by the magnification (or reduction) that is selected. As a rule, the largest possible extension is that which also defines the areal size of the image sensor. The largest possible image of the object field in the image plane thus, as a rule, defines the size of the image sensor.

Image sensors are often embodied as CCDs and are referred to as “CCD video chips.” It is known that conventional CCD video chips react, for example, outstandingly to IR (infrared) light, whereas the human eye cannot perceive infrared. It is thus possible, for example, to acquire infrared image information via the image acquisition unit of the video microscope and inject it for the user by so-called image injection (image overlay using small displays via prisms or (splitter) mirrors), in alternative or superimposed fashion, into the visual observation beam path of the surgical microscope. The designation “video” encompasses, in the context of the invention, all imaginable image signal technologies that, by photoelectronic conversion, convert image information obtained from a beam path into electronic signals, and convert the latter in turn (e.g. via a display) into visually perceptible image data. It is thus not limited to video technology with regard to electronic film recording technology, but also encompasses static recording of static images (photos from digital cameras), and also electronic recording, processing, and depiction of partial image information using a wide variety of respectively available image/film recording technologies. For purposes of the invention, the term “video camera” therefore also encompasses subject matter that is referred to using the term “digital camera.”

Also known in this regard from the existing art is DE 100 04 891 C2, which discloses a focal surface for optoelectronic image acquisition systems having an arrangement of detectors for image acquisition and having a detector carrier for holding the detectors, the detectors each being manufactured from at least one silicon element, and the focal surface and/or detectors having a curvature for acquiring a curved image field. The detectors are configured flexibly, the silicon element being thinned and being connected to a flexible carrier substrate.

US 2010/0178722 A1 further discloses a manufacturing process for an image-producing sensor in which light-sensitive semiconductor cells are connected using extensible connections, and this arrangement is then transferred, with the aid of a pre-extended elastomer punch, onto a non-flat substrate.

WO 2008/143635 A1 additionally discloses optical devices and systems that are manufactured at least partly using pressure-based assembly and integration of device components. Optical systems of the present invention encompass semiconductor elements that are assembled, organized, and/or integrated with other device components using pressure techniques. A plurality of shapes, component densities, and component positions of optical systems of the aforesaid kind can thereby be implemented.

US 2009/0261394 A1 furthermore discloses a method for manufacturing an image sensor in which the layers thereof can be pressed or applied onto a flat or non-flat substrate. In this context, each layer is pressed with the aid of an elastomer punch into a vacuum mold.

Lastly, US 2010/0059863 A1 very generally discloses semiconductor circuits that can be extended, compressed, and bent in order to enable implementation of flexible electronic and optoelectronic devices.

The manner (software or hardware) in which the electronic image signals are further processed is secondary in terms of the invention. What is critical for the invention is the nature of the image acquisition (conversion of optical signals into electronic signals) and the specific configuration of the image sensors or image converter cells in the image sensors, as well as, if applicable, the presentation (conversion of electronic signals into optical image information) for the user or users.

An “image sensor” or video chip is, however, to be understood for purposes of the invention as an image acquisition unit or image converter chip in the most general form. What is critical according to the present invention is that a visual image signal can therewith be converted into correlated electronic image signals that, subsequently thereto, can be in turn presented via a display to a user. The particular nature and arrangement of the photoelectronic image converter cells is a subject of the invention.

Assistant's outputs can often also be embodied selectably as video observation beam paths or video outputs.

Both the main observation beam path and the assistant's observation beam path often have the capability, via splitter mirrors, prisms, or the like, of injecting information into the imaging beam path so as to make additional information available to the main observer and the assistant without requiring them to look away from the microscope.

A display is to be understood as an image presentation unit that conveys to a user an image generated by video technology. It can be a flat two-dimensional display (e.g. an LCD screen or a monitor) with or without apparatuses for 3D presentation. It also encompasses, however, those apparatuses that reproduce images monoscopically or stereoscopically and, for example, inject them into the imaging beam path of the surgical microscope, or present the image monoscopically or stereoscopically to the user in head-up displays or on a screen (display) mounted on the microscope stand (see US 2009/0190209 A1; FIG. 6).

The invention refers, in the preferred embodiment, to a surgical microscope having at least one video channel. The Claims are, however, to be construed broadly, so that other magnification apparatuses such as, for example, endoscopes or laparoscopes are embraced thereby, provided they serve in the same way, and are correspondingly usable, for surgery and for video observation.

In order to select an enlarged image segment, in the case of microscopes individual lenses or lens groups are usually arranged displaceably so as thereby to implement a “zoom” optic that enables stepless changing between different focal lengths.

EP 1431796 B1 may be mentioned here by way of example as existing art with regard to a zoom for a surgical microscope. Another zoom optic specifically for video attachments on microscopes is indicated in WO 01/79910 A1. The complexity and fragility of the zoom is already evident from the Figure published with the Abstract.

A feature common to all imaging optics for modifying a focal length is that they are of comparatively complex construction. Lenses or lens groups that are displaced in the optical imaging optic must be precisely guided so that as few aberrations as possible are produced. The guides can also, however, be subject to a certain amount of wear, and in addition they can exhibit different guidance properties as a function of temperature. Optical imaging optics having multiple lens groups, guides, and the like also often react sensitively to impact, and must therefore be handled very carefully during transport and operation.

A further disadvantage is the fact that the complex imaging optics are susceptible to misalignment. Severe temperature fluctuations, in particular, can cause the lens elements to be no longer optimally spaced or aligned. Zoom optics whose length is modified when zooming furthermore have a tendency to draw in dust, which may settle on the lens elements and on the image sensor and cause image problems or decreased quality.

Without complex correction calculations and without correspondingly expensively produced lens elements, zoom optics having a wide zoom range exhibit considerable aberrations, often in the end positions. For surgical microscopes in particular, very complex lenses must therefore always be used.

In summary, it can be said of conventional zoom optics that the technology has been mastered and that microscopes having zooms function well, but that these zooms exhibit the disadvantages indicated above, which have to do in particular with the movability and number of optical and mechanical components. Zoom optics having electroactive lens elements (rubber lenses) are simple and do not have the disadvantages indicated, but on the other hand are often not adequate with regard to image quality properties.

### SUMMARY OF THE INVENTION

An object of the invention is therefore to describe an approach to avoiding these problems in zoomable video observation beam paths. The intention in particular is to describe an improved video camera and an improved microscope with which zooming can occur with no need to use conventional zoom optics having bulky moving parts. A particular intention is to make possible selection of a larger or smaller image region from the object field, and select the magnification of that region (“zoom”), by means of the simplest possible actions using the fewest possible optical and mechanical components. The lens elements themselves are to remain unchanged in this context, i.e. “rubber lenses” are out of consideration as an alternative.

According to the present invention this object is achieved by a novel specially modified image sensor (video chip) of the kind cited initially, in which the relative position of the photoelectronic image converter cells is modifiable by the fact that, for example, the size of the areal extension of the image sensor in the image plane is modifiable and the area modification occurs, for example, by a) applying a tensile or compressive force onto a reversibly (if applicable, elastically) deformable substrate, or b) by applying an electrical voltage to a piezoelectric or electromicromechanical substrate. Because the chip is arranged in stationary fashion in an image plane, it requires no displacement mechanisms (such as, for example, in the case of a zoom).

The object of the invention is also achieved with a video camera having an optical imaging optic that encompasses an image sensor according to the present invention. In other words, with the aid of the invention it is also possible to construct novel video cameras that can dispense with conventional zoom systems and rubber lenses but can nevertheless present zoom effects.

Lastly, the object of the invention is also achieved with a microscope, in particular with a surgical video microscope, having an optical imaging optic that encompasses an image sensor according to the present invention or a video camera according to the present invention.

According to the present invention, the imaging optic thus does not change its optical imaging properties, but instead the image sensor changes its structural image acquisition properties, by the fact that the relative positions of its photoelectronic image converter cells in the image plane are modified.

The basic idea of the invention is thus that the fundamentally constant pixel ratio of image converter cells to display pixels is exploited in order to generate a zoom effect. Thus, for example, if all the pixels of an image sensor are connected to all the pixels of a display (e.g. 1:1), when the entire area of the entire image of the object field is completely utilized, the entire object field can be depicted on the display in accordance with its complete image. If, however, the photoelectronic image converter cells according to the present invention then shift closer to one another according to the present invention, i.e. if the area covered by them within the image of the object field in the image plane becomes smaller, this reduced-size image segment is depicted on the display in magnified fashion (i.e., as before, on the entire display) utilizing, as before, all the pixels of the display. This corresponds to a typical zoom operation or magnification that is achievable by means of a conventional zoom. In contrast thereto, however, according to the present invention no lens elements are shifted and no imaging optics are modified.

What is achieved according to the present invention is thus that with even a simple optical imaging optic, in particular an optical imaging optic having a fixed focal length, it is possible to switch between various image segments and magnifications, in particular steplessly. For this, the areal extension of the image sensor or the spacings between the respectively adjacent optoelectronic image converter sensors that is/are arranged in the image plane of the optical imaging optic are modified. It is thereby possible to sense either the entire image generated by the optical imaging optic in the image plane, or in fact only a part thereof. If only a portion of the generated image is sensed using all the image converter cells, this then corresponds to a enlargement of a segment or to a shortening of the focal length in the microscopic main beam path (observation beam path) or to a lengthening of the focal length in the beam path of an imaging optic of a video camera. In this fashion, an image segment can be displayed at reduced size, or the image of the image segment presented on the display can be presented in magnified fashion. The modification according to the present invention of the image segment is thus accompanied by the change in imaging scale.

Advantageously, there is therefore no need to provide laboriously corrected lenses and complex guides for said lenses or lens groups, in order to allow zoom effects to be achieved. Because only one fixed focal length is necessary in principle, it can also be optimally configured in terms of its imaging performance, and no compromises need to be made with regard to image quality at the end positions of the zoom optic, nor do particularly expensive corrected lens systems need to be used. A simple optical imaging optic is moreover less susceptible to misalignment and/or severe temperature fluctuations as compared with a conventional zoom optic. Furthermore, a fixed-focal-length optic does not change its length as necessary, so that dust also cannot be drawn in. The engineering, assembly, and maintenance of a corresponding imaging optic are also simplified for the reasons listed.

Motor drives for the conventional zoom, linkages, guides, bearings, etc., are superfluous. It is also noted advantageously that the vibrations, noise, etc. generated by the conventional drive systems of conventional zooms are eliminated. Lastly, in the absence of appreciable mechanisms and appreciable distances that need to be traveled by relatively large components (lens elements or lens systems), the zoom operation also occurs substantially more quickly than with conventional zoom optics. Specifically in the field of surgical microscopy, this is an enormous advantage for the user or surgeon, and thus also for the patient.

The actual structure of an image sensor according to the present invention can assume a wide variety of forms, all of which are covered and protected by the invention. What is critical is that the individual image converter cells are movable relative to one another, preferably displaceable with respect to one another in the image plane of the imaging optic.

One possibility for bringing this about is electromicromechanical structures, comparable to the micromirror arrays such as those indicated e.g. in DE 10116723 C1. Those skilled in the art of developing electromicromechanical structures of course have leeway here for developments in detail; with a knowledge of the invention, however, such further developments of micromechanical arrays known per se represent merely the activity of one skilled in the art. As already mentioned, what is important is to mount the image converter cells movably or displaceably relative to one another. The electrical contacts to the image converter cells must of course be maintained during and after their positional change. The image converter cells along with their image signal receiving surfaces must of course not move substantially out of the image plane. Micromechanical arrays of this kind are manufactured micromechanically and thus permit mass production with high quality and reproducible accuracy. The image converter cells are held on carriers of the arrays, the carriers being movable by way of a capacitive or thermal actuator apparatus. Electric fields are used in the case of a capacitive actuator apparatus, while with a thermal actuator apparatus, for example, current intensities of different levels, and associated differential heating, of the micromechanical structures causes a deflection of the carriers. Bimetallic constructions can, in this instance, very efficiently permit relatively long travel distances. To enable a simple effect over the entire image acquisition area, adjacent carriers are preferably braced against one another so that the relative motion between two adjacent image converter cells also automatically produces an equal-distance displacement or motion of the closest and next-closest neighboring image converter cells.

According to the article about digital light processing (DLP) technologies entitled “DLP Technologie—nicht nur für Projektoren and Fernsehen” (“DLP Technologies—Not Only For Projectors and TVs”) on pages 32-35 in Photonik 1/2005, the micromirror arrays or digital micromirror device (DMD) technologies, having XGA resolution and enormously fast switching operations of up to 10 gigabits per second, can in some circumstances also be used to acquire zoomed and unzoomed images almost simultaneously, i.e. in real time or so quickly that the human eye cannot perceive it. With this new technology according to the present invention it is thus possible, using one and the same configuration (and with corresponding electronic circuitry), to simultaneously acquire both non-zoomed and zoomed image segments or magnifications and, if applicable, present them on different displays. Such depictions can of course also be provided as picture-in-picture on only one display, so that if necessary a user can simultaneously see depicted, alongside his or her normal view of an object field, an enlarged image segment as well. In the case of surgical video stereomicroscopes, the non-zoomed view could optionally be overlaid onto the object field in one of the two partial observation beam paths, while the zoomed image segment can be injected into the other partial observation beam path, so that by closing one eye or the other the user obtains on the one hand an overview and on the other an enlarged detail view of the specimen in the object field.

A variant for implementing the basis for the mutually displaceable photoelectronic image converter pixels (=image converter cells) is based on polymers, and in particular on the group of the electroactive polymers (EAPs).

This variant is particularly advantageous. The substrate here is made up of a polymer or a dimensionally stable gel. The properties of polymers and gels can be controlled over wide ranges, so that a specific elasticity of the substrate can easily be established. It has also been known for some time that organically based electronic circuits can be manufactured. This technology can be looked up on the Internet using the terms “organic electronics” or “polymer electronics.”

The following terms have been introduced in this context: organic electronics is a sub-field of electronics that uses electronic circuits made of conductive poles or smaller organic compounds. The terms plastic electronics, or more commonly polymer electronics (also “polytronics”), are also used synonymously. A general feature of all concepts is, as a rule, that circuits are designed using macromolecules and using multimolecular structures having larger dimensions as compared with conventional electronics.

This technology can readily be used for the utilization according to the present invention. A feature of polytronics (also called “plastic electronics”) is the use of microelectronic components on carrier materials made of organic foils and having conductive paths and components produced from conductive organic molecules (organic semiconductors). The molecules (principally polymers alongside monomers and oligomers) are pressed, bonded, or otherwise applied onto the foils in the form of thin films or small volumes.

Depending on their chemical composition, polymers can possess electrically conductive, semiconductive, or insulating properties.

This invention, which makes use of polytronics, is not limited to exclusive approaches. Combinations can therefore of course also be provided, for example by the fact that each of the two image sensors additionally encompasses image converter cells that are in turn displaceable with respect to one another.

An embodiment of the invention results from the use of a flexible substrate comparable to the electroactive substances or polymers (EAPs), by utilizing the known materials of rubber lenses that are deformed not by the application of electrical voltages but by mechanical forces. The image converter cells can thus be positioned relative to one another on or in this substrate. The spatial extension of the image sensor, or the distance between the image converter cells, can be varied by a compressive/tensile force that is exerted, comparably to the known rubber lenses, on the substrate. As already mentioned, the change in size of the substrate can occur in principle by application of a tensile or compressive force onto the substrate or by application of an electrical voltage to piezoelectric positioning elements.

In the variant, the change in size is produced by actuators that pull the substrate apart, or compress it, at its edges with varying force.

With the plastics (polymers) there are thus two approaches to implementing the invention: on the one hand via EAPs and on the other hand using conventional (electro)mechanically deformable polymers.

Electrical components, as well as the electrical wiring itself, can consequently be constructed from plastic. Sumitomo Chemical, for example, offers corresponding elastic conductive polymers and elastomers (e.g. Esprene 505A). When a polymer or elastomer is used for the substrate of the sensor according to the present invention, on the one hand the mechanical, but on the other hand also the electrical material properties can therefore be optimally established.

When a mechanically deformable elastic polymer is used, in principle only the application of a tensile force or a compressive force is necessary, since the substrate, because of its elasticity, reassumes its original shape without action of a force. Because of hysteresis effects, however (as a rule, without the action of a force the substrate no longer assumes its original shape with 100% accuracy), it may be advantageous to apply both tensile and compressive forces alternatingly to the elastic substrate. In this case it is also sufficient in principle if the substrate is plastically deformable.

The forces can be introduced in point-like or linear fashion into the substrate. With point-like introduction of the forces in particular, however, it is to be expected that not only the size but also the shape of the substrate will change (for example, upon introduction of a tensile force the substrate is further elongated at the force application points). This change of shape is advantageously corrected in an electronic image processing unit that is located downstream from the sensor according to the present invention, so that an undistorted image is available at the output of the image processing unit (for example, upon introduction of a tensile force the image constituents at the force application points are “pushed inward” by software). Such algorithms are known in principle and will therefore not be explained further at this juncture.

Alternatively, the entire substrate can be constructed piezoelectrically, so that it itself functions as a carrier of the image converter cells. Its own elongation or stretching or shrinkage thus brings about the positional displacement of the image converter cells.

In the variant of the invention having a piezo substrate, the change in size is produced by an internal force in the substrate, namely with the aid of the piezoelectric effect. It is known that by applying an electrical voltage to a piezo crystal, the latter's size can be modified. Multiple piezo crystals can also be connected in series in order to intensify the change in size. Here as well, an image processing unit downstream from the sensor according to the present invention can of course account for any geometrical changes in the substrate.

All the approaches according to the present invention so far described, and the variants and further developments yet to be disclosed below, can moreover also be combined, in the respective imaging optic, with conventional electroactive lenses (rubber lenses) and/or conventional zoom optics.

Both in the case of the substrate comparable to the conventional electroactive substances and with the rubber lenses, and also in the case of a substrate made of piezoelectric substances, electrical pickoff from the photoelectric image converter cells is brought about in each case by way of correspondingly elastic connecting leads.

“Elastically and/or plastically deformable” is to be considered, in the context of the invention, with reference to the “zoom factor” to be achieved and the structural forces occurring in that context. In principle, an effort will be made to produce a change in the size of the substrate using the smallest possible forces, so that unnecessary mechanical stress is not exerted on the structure (i.e. the sensor according to the present invention, the actuators, and the apparatus in which the actuators are anchored). Especially in the context of large zoom factors, it is therefore preferable to use relatively easily deformable materials for the substrate. If only a small zoom factor is required, however, a material that is correspondingly more difficult to deform can then be used (assuming identical forces).

Advantageous embodiments and further developments of the invention are evident from, and are disclosed by, the dependent claims and the description in combination with the Figures of the drawings.

It is advantageous in light of what has so far been described if the size of the photoelectronic image converter cells is substantially constant. With this configuration, the photoelectronic image converter cells “float,” so to speak, on a substrate whose size can be modified. When the substrate is made larger, the distances between the image converter cells also become larger. In particular, these image converter cells can therefore be made (as previously) of silicon, and can be contacted to the elastic polymer substrate via suitable contacts.

The wiring system of the photoelectronic image converter cells arranged in floating fashion can thus once again be taken from electrical paths in a substrate made of a polymer.

It is furthermore advantageous if the photoelectronic image converter cells are elastic and are equipped for a modification of their size. With this variant, the image converter cells also participate (at least to a certain degree) in an expansion of the substrate and are likewise expanded in that context. Advantageously, the interstice occurring in that context between the image converter cells is smaller than with the embodiment recited above or, in a particular variant of the invention, is also not present at all. Advantageously, even with an expanded substrate, all of the incident light is then used for conversion into an electronic signal. The sensitivity of the photoelectronic image converter cells can therefore be lower, and a tendency to image noise is thus diminished. It is advantageous in this connection if the photoelectronic image converter cells are made of a polymer.

Lastly, it is advantageous if the photoelectronic image converter cells are arranged in multiple layers with an offset. With this variant, photoelectronic image converter cells of layers located lower down are embedded into an at least partly transparent substrate. When the substrate is then made larger, an interstice then occurs in the context of the photoelectronic image converter cells of layers located higher up, especially if they have a constant size. Incident light penetrates through the at least partly substrate in this region and strikes photoelectronic image converter cells of layers located lower down. This variant of the invention is therefore particularly suitable for the use of photoelectronic image converter cells of constant size (or those that cannot completely follow an expansion of the substrate) with no need to accept darkening of the sensed image. The image converter cells can be arranged in two layers, but also in several.

Be it noted at this juncture that the variants recited for the image sensor according to the present invention, and the advantages resulting therefrom, also refer in the same way to the video camera according to the present invention and to the microscope according to the present invention.

The above embodiments and further developments of the invention can be combined in any desired manner.

### BRIEF DESCRIPTION OF THE DRAWINGS

The present invention will be further explained below with reference to exemplifying embodiments described in the schematic Figures of the drawings, in which:

FIG. 1 shows a first example of an image sensor according to the present invention, having photoelectronic image converter cells of constant size;

FIG. 2 shows a second example of an image sensor according to the present invention, having photoelectronic image converter cells of variable size;

FIG. 3 shows a third example of an image sensor according to the present invention, having photoelectronic image converter cells that are arranged in multiple layers;

FIG. 4 shows the image sensor of FIG. 3 in cross section;

FIG. 5 shows a fourth example of an image sensor according to the present invention, having photoelectronic image converter cells that are arranged in multiple layers; and

FIG. 6 shows the image sensor of FIG. 5 in cross section.

In the Figures of the drawings, identical and similar parts are provided with the same reference characters; and elements and features of similar function are, unless otherwise stated, provided with identical reference characters but different indices.

### DETAILED DESCRIPTION OF THE INVENTION

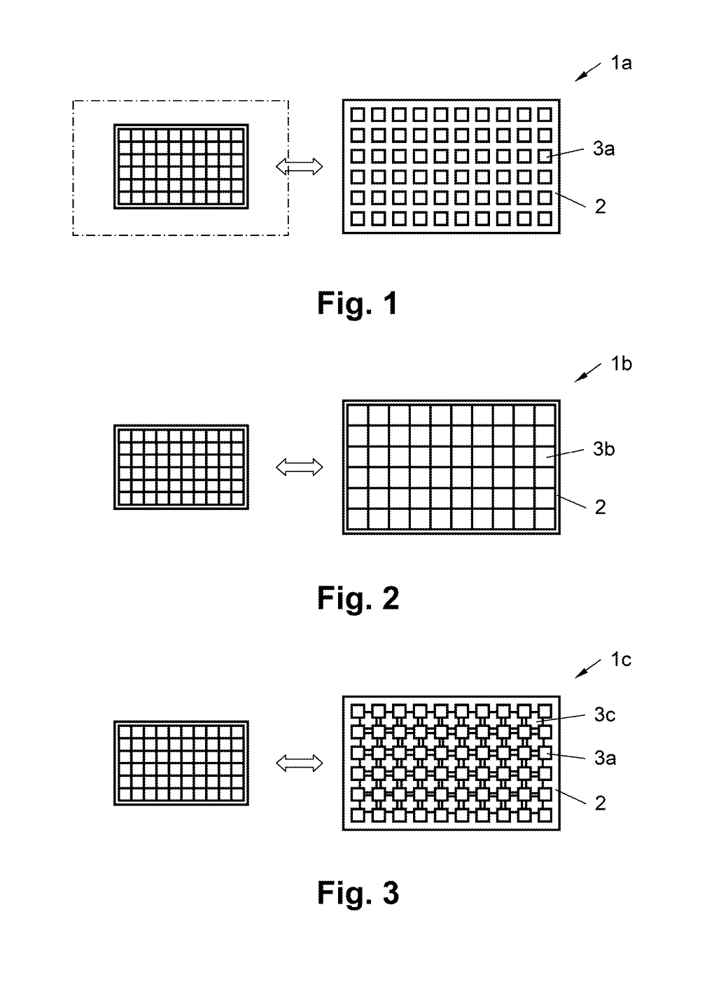

FIG. 1 shows a first example of an image sensor 1a according to the present invention. It encompasses a substrate 2 as well as multiple photoelectronic image converter cells 3a arranged thereon or therein. Substrate 2 is preferably elastic, and can change in size. Substrate 2 can, for that purpose, be made of a polymer.

Image sensor 1a is depicted at its original size in the left image of FIG. 1, and with an expanded substrate 2 in the right image. In this example, as is readily apparent, the size of photoelectronic image converter cells 3a is constant, i.e. upon an increase in the size of substrate 2, only the interstices between image converter cells 3a increase in size. Photoelectronic image converter cells 3a can be made, for example, of silicon.

Advantageously, an acquired image segment can thereby be modified even if an imaging optic placed in front of image sensor 1a does not encompass a zoom function. The invention nevertheless does not, of course, exclude video cameras and microscopes that comprise both a new image sensor according to the present invention and a conventional zoom. With such a configuration, the positive effects described here of an image sensor according to the present invention could be combined with the positive effects of a conventional zoom. In the case of video cameras, for example (e.g. in mobile telephones or the like), alongside the conventional mechanical and electronic zoom an additional zoom magnification step could be provided, namely the one by means of an image sensor according to the present invention. This would result in an enhancement of imaging capabilities at approximately the same overall size.

In the left image of FIG. 1, a dot-dash frame indicates the image generated by the optical imaging optic in an image plane. Because image sensor 1a in this state is relatively small in relation thereto, only part of the generated image is actually sensed by photoelectronic image converter cells 3a, corresponding substantially to magnification of a segment.

In the right image, on the other hand, the entire image generated by the optical imaging optic in the image plane is sensed. The left image therefore corresponds to an increase in the magnification of the zoom, and the right image to a reduction in the magnification of the zoom, but with no need to actually modify the focal length or image segment (zoom) of the optical imaging optic for that purpose.

The optical imaging optic can therefore be kept relatively simply and, in particular, can have only one fixed focal length. If a zoom objective is nevertheless used, the zoom range can thus be expanded with image sensor 1a according to the present invention.

Advantageously, image sensor 1a according to the present invention can therefore be used in a digital camera for both still and moving images. The video camera can be of any construction; in particular, the digital camera can also be part of a mobile telephone. The digital camera can, however, also be used in the medical sector; for example, the video camera can be provided for attachment to a microscope, in particular a surgical microscope. The surgical microscope can have a video adapter for that purpose. Sensor 1a according to the present invention can of course also be installed directly in a microscope or, for example, in an endoscope. Many possible uses are conceivable here, for example including in the industrial sector; to list them would exceed limitations, but they are also encompassed by the basic inventive idea. In principle, image sensor 1a can substitute for any presently used conventional image sensor.

FIG. 2 now shows a variant of an image sensor 1b that is very similar to image sensor 1a of FIG. 1, except that photoelectronic image converter cells 3b are elastic and can be modified in terms of their size. The elastic photoelectronic image converter cells 3b can, for that purpose, be made of a polymer. The light incident onto sensor 1b can thereby be optimally sensed, since no interstices (which sense no light) are produced between image converter cells 3b upon “zooming.”

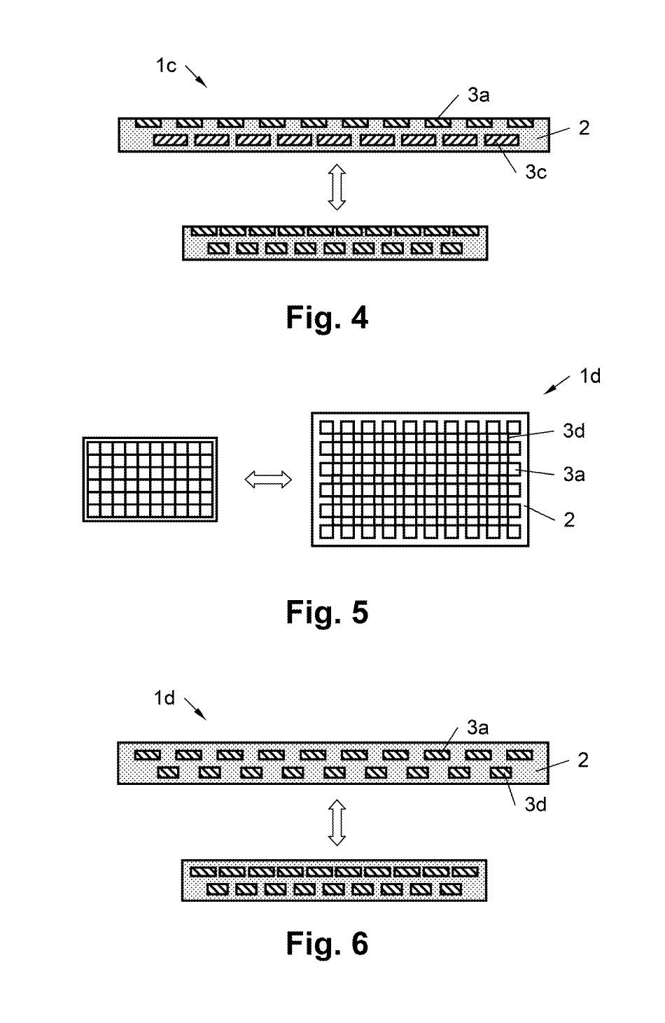

FIGS. 3 and 4 show a further alternative configuration of an image sensor 1c according to the present invention. In this sensor 1c, photoelectronic image converter cells 3a and 3c are arranged in two layers. Image converter cells 3a are located directly at the surface of substrate 2 that is struck by light. Image converter cells 3c, on the other hand, are located in a layer of substrate 2 that is somewhat lower down, and are arranged with an offset from image converter cells 3a.

In the left image of FIG. 3 only image converter cells 3a are provided for image sensing; upon expansion of substrate 2, however, image converter cells 3c located lower down are also exposed and are in that fashion used for image sensing. For this purpose, substrate 2 is embodied in least partly transparent fashion.

In the present example (FIG. 4), image converter cells 3a have a constant size, whereas image converter cells 3c are variable in terms of their size. In the case of FIG. 3 a gradual increase or decrease in the size of the effective area of cells 3c is also produced. This is not an obligatory condition, however, as shown by image sensing sensor 1d shown in FIGS. 5 and 6. This sensor is very similar to image sensing sensor 1c of FIGS. 3 and 4, but image converter cells 3d of the lower layer have, like image converter cells 3a of the upper layer, a constant size. In addition, image converter cells 3a are set somewhat lower down so that they are completely covered by substrate 2.

In the preceding examples, rectangular (strictly speaking, square) photoelectronic image converter cells 3a to 3d are always depicted. This is naturally not an obligatory condition. Other geometric shapes for image converter cells 3a to 3d are of course also possible, in particular circular, hexagonal, or octagonal image converter cells 3a to 3d.

Image converter cells 3a to 3d can also be equipped for light of a different wavelength. For example, image converter cells 3a to 3d can be provided for red, green, and blue. It is also conceivable to place different color filters in front of image converter cells 3a to 3d, for example once again for red, blue, and green. Image converter cells 3a to 3d can of course also be designed for an electromagnetic radiation in the invisible wavelength region, for example for infrared or ultraviolet light.

Electronic circuits that are provided for image sensors of conventional design, for example in order to prepare and further process the signal obtained from the sensor, can of course also be used, in principle without modification, for image sensor 1a to 1d according to the present invention.

It is also conceivable for photoelectronic image converter cells 3a to 3d to be switched in or out, for example upon “zooming” in the context of FIG. 5 or 6. Upon an increase in the size of substrate 2, for example, image converter cells 3a to 3d located at the edge of substrate 2 can be switched out in order to reduce the size of the region sensed by sensor 1a to 1d. Conversely, image converter cells 3a to 3d are then switched back in when the size of substrate 2 is decreased.

For all the variants of image sensor 1a to 1d according to the present invention that are depicted, the change in the size of substrate 2 can occur a) as a result of application of a tensile or compressive force, if substrate 2 is made of an elastically and/or plastically deformable material, or b) by application of an electrical voltage, if substrate 2 is made of a piezoelectric material. In case a) an actuator that operates on the piezoelectric principle can of course also be used for this. In this case, however, the change in the size of substrate 2 is produced not by internal piezoelectric forces but by external piezoelectric forces. Other actuators are naturally also usable in principle, in particular linear motors, for example electromagnetic, pneumatic, or hydraulic linear motors. Implementation thereof at a miniature scale is known in principle from microelectromechanical systems (MEMS) technology, in which tiny machines are, for example, etched out by photolithographic methods from a wide variety of materials; this therefore does not need explanation in further detail.

In conclusion, it is noted that the variants of image sensor 1a to 1d according to the present invention that are presented represent only a selection from the many possibilities, and are not to be utilized to limit the range of application of the invention. The variants depicted can of course be combined and modified in any way. For example, the teaching of FIGS. 1 and 2 can be combined by providing, for image sensor 1b of FIG. 2 as well, elastic image converter cells 3b that are nevertheless not as elastic as substrate 2 and are thus also less elastic than image converter cells 3a of FIG. 1. Upon expansion of substrate 2, interstices are therefore produced in principle between image converter cells 3b, but end up being smaller than the interstices depicted in FIG. 1.

In addition, image sensors 1c and 1d can of course also comprise more than two layers. It should therefore be an easy matter for one skilled in the art to adapt the invention to his or her needs on the basis of the considerations presented here, without thereby leaving the range of protection of the invention. In addition, it is noted that parts of the apparatuses depicted in the Figures can also form the basis for independent inventions.

### LIST OF REFERENCE CHARACTERS

1a to 1d Image sensor
2 Substrate
3a to 3d Photoelectronic cells

What is claimed is:

1. An image sensor, comprising:
a deformable substrate having multiple photoelectronic image converter cells;
wherein the cells define an image-sensing surface area, the image-sensing surface area being modifiable by application of a tensile or compressive force onto the deformable substrate.

2. The image sensor according to claim 1, wherein the deformable substrate comprises at least one polymer.

3. The image sensor according to claim 2, wherein the deformable substrate comprises an electroactive polymer (EAP) to which an electrical voltage can be applied in order to deform the EAP.

4. The image sensor according to claim 1, further comprising a piezoelectric apparatus connected to the deformable substrate, wherein the tensile or compressive force is applied by the piezoelectric apparatus.

5. The image sensor according to claim 1, wherein the deformable substrate is a piezoelectric substrate, and the tensile or compressive force is applied by application of an electrical voltage to the piezoelectric substrate.

6. The image sensor according to claim 1, wherein each of the photoelectronic image converter cells has a substantially constant image-sensing area.

7. The image sensor according to claim 1, wherein each of the photoelectronic image converter cells are elastic and have a modifiable image-sensing area.

8. The image sensor according to claim 1, wherein the photoelectronic image converter cells are arranged in an upper cell layer and a lower cell layer, wherein individual cells of the upper cell layer are offset relative to individual cells of the lower cell layer.

9. The image sensor according to claim 1, wherein each of the photoelectronic image converter cells is made of at least one polymer.

10. The image sensor according to claim 1, wherein each of the photoelectronic image converter cells is made of silicon.

11. A video camera, video microscope, or surgical video stereomicroscope, comprising:
an image sensor, the image sensor including a deformable substrate having multiple photoelectronic image converter cells, wherein the cells define an image-sensing surface area, the image-sensing surface area being modifiable by application of a tensile or compressive force onto the deformable substrate; and
an imaging optic for forming an image on the image sensor.

12. The video camera, video microscope, or surgical video stereomicroscope according to claim 11, wherein the imaging optic has a fixed focal length.
